(19) United States
(12) Patent Application Publication
(10) Pub. No.: US 2025/0293035 A1
(43) Pub. Date: Sep. 18, 2025

(54) METHOD OF ETCHING INDIUM-BASED SEMICONDUCTOR MATERIALS

(71) Applicant: OXFORD INSTRUMENTS NANOTECHNOLOGY TOOLS LIMITED, Abingdon (GB)

(72) Inventors: Katie HORE, Abingdon (GB); Kasia STOKELEY, Abingdon (GB); Andrew NEWTON, Abingdon (GB); Kevin POWELL, Abingdon (GB)

(21) Appl. No.: 18/860,137

(22) PCT Filed: Apr. 26, 2023
(86) PCT No.: PCT/GB2023/051114

§ 371 Date: Oct. 25, 2024

(30) Foreign Application Priority Data
Apr. 27, 2022 (GB) 2206130.3

(51) Int. Cl. H01L 21/3065; H01J 37/32; H01L 21/308

(52) U.S. Cl. CPC H01L 21/3065; H01J 37/321; H01J 37/32449; H01J 37/32467; H01J 37/32724; H01L 21/308; H01J 2237/2001; H01J 2237/2007; H01J 2237/3346

(57) ABSTRACT

A method of etching into an indium-based semiconductor material. The method comprises mounting a substrate comprising the indium-based semiconductor material directly on a substrate support structure in a plasma processing chamber, wherein the indium-based semiconductor material forms a surface of the substrate, said surface carrying a patterned mask and being arranged distal to the substrate support structure. The plasma processing chamber contains solid silicon arranged to be exposed to plasma generated inside the plasma processing chamber, the exposed surface area of the solid silicon being at least 1 times the area of the surface of the substrate carrying the patterned mask which is not covered by the patterned mask. The method further comprises: establishing a flow of an etch gas mixture into the plasma processing chamber, the etch gas mixture comprising an inert gas and a chlorine-bearing gas configured to release chlorine radicals when present in plasma generated from the etch gas mixture; and generating a plasma from the etch gas mixture within the plasma processing chamber such that the solid silicon is exposed to the plasma, thereby generating silicon-containing species in the plasma from the solid silicon, and simultaneously applying a radio frequency (RF) bias voltage to the substrate support structure, whereby the portion of the surface carrying the patterned mask that is not covered by the patterned mask is etched by the plasma comprising the generated silicon-containing species so as to form one or more etched features in the indium-based semiconductor material.

### FIELD OF THE INVENTION

The invention relates to a method of etching into indium-based semiconductor materials, in particular indium phosphide and its alloys.

### BACKGROUND

Indium-based semiconductor materials find application in a range of semiconductor devices such as optoelectronic devices (for examples lasers and photodiodes), transceivers and photovoltaic devices. In this specification, “indium-based semiconductor material” means a compound semiconductor comprising indium. Indium phosphide (InP) is a notable example of an indium-based semiconductor material. Other examples of indium-based semiconductor materials include alloys of indium phosphide, including ternary alloys (e.g. indium gallium phosphide, InGaP) and quaternary alloys (e.g. indium gallium arsenide phosphide, InGaAsP), and indium antimonide (InSb). By contrast, semiconductor materials that contain only trace levels of indium (e.g. where indium is present only as a dopant) are not indium-based semiconductors since indium does not appear in the compound formula of these materials. For example, silicon (Si) doped with indium is not an indium-based semiconductor. Indium typically forms at least 5% by weight of indium-based semiconductor materials. Plasma etching processes for etching indium-based semiconductor materials typically employ gas mixtures including a chlorine-bearing gas (e.g. molecular chlorine, Cl₂, or boron trichloride, BCl₃) that releases chlorine radicals into the generated plasma. Chlorinated species in the plasma contribute to etching of the indium-based semiconductor material by their chemical interaction with it.

As noted above, InP is a prominent indium-based semiconductor material and is by far the most commonly-utilised material of this class in industrial processes for manufacturing semiconductor devices. Devices made of indium-based semiconductor materials such as InP are typically manufactured by etching, using a plasma, into a substrate in which the indium-based semiconductor material forms either a layer in the substrate (e.g. an epitaxial layer) or the entirety of the substrate (e.g. in the form of a wafer made from the indium-based semiconductor material). Processes suitable for industrial-scale etching of indium-based semiconductor material ubiquitously employ etch gas mixtures containing a chlorine-bearing gas (i.e. a gas configured to release chlorine-containing radicals when present in a plasma) for producing the plasma.

To date, devices formed of indium-based semiconductor materials have been successfully fabricated in “carrier-based” processes, where the substrate to be etched is placed on a separate carrier wafer, typically made of silicon, on which it lies while being etched. However, the suitability of such processes for industrial scales of production is severely limited by practical considerations. For example, transporting the carrier wafer and the substrate to be etched under vacuum is extremely difficult in systems of the kind favoured for industrial scales of production where high throughput is required, in particular cassette-based systems. In cassette-based systems, multiple substrates (e.g. wafers) to be etched are typically loaded into a “cassette” inside a load lock (i.e. a second chamber that is in communication with the main plasma processing chamber but which may be sealed and pressurised separately). Moreover, the presence of the carrier wafer makes it difficult to precisely controlling certain physical conditions in the vicinity of the wafer being etched, which can lead to inconsistency between the devices manufactured from one iteration to the next.

Attempts to provide industrial-scale processes for etching into InP and other indium-based semiconductor materials have generally not been successful in producing devices of the consistency and high quality required for commercial production. There is thus a need for a process for etching into indium-based semiconductor materials capable of producing consistent, functioning devices at high throughput.

### SUMMARY OF INVENTION

The invention provides a method of etching into an indium-based semiconductor material, the method comprising:
mounting a substrate comprising the indium-based semiconductor material directly on a substrate support structure in a plasma processing chamber, wherein the indium-based semiconductor material forms a surface of the substrate, said surface carrying a patterned mask and being arranged distal to the substrate support structure,
wherein the plasma processing chamber contains solid silicon arranged to be exposed to plasma generated inside the plasma processing chamber, the exposed surface area of the solid silicon being at least 1 times the area of the surface of the substrate carrying the patterned mask which is not covered by the patterned mask; the method further comprising:
establishing a flow of an etch gas mixture into the plasma processing chamber, the etch gas mixture comprising an inert gas and a chlorine-bearing gas configured to release chlorine radicals when present in plasma generated from the etch gas mixture; and
generating a plasma from the etch gas mixture within the plasma processing chamber such that the solid silicon is exposed to the plasma, thereby generating silicon-containing species in the plasma from the solid silicon, and simultaneously applying a radio frequency (RF) bias voltage to the substrate support structure, whereby the portion of the surface carrying the patterned mask that is not covered by the patterned mask is etched by the plasma comprising the generated silicon-containing species so as to form one or more etched features in the indium-based semiconductor material.

As noted above, the phrase “indium-based semiconductor material” in this specification means a compound semiconductor comprising indium. Indium-based semiconductor materials may be doped. In the method of the invention, a substrate comprising an indium-based semiconductor material (which forms the surface of the substrate that is to be etched) is directly mounted on a substrate support structure. This indium-based semiconductor material forms the surface of the substrate that is to be etched, which is the surface on which the patterned mask is carried. In some implementations, the substrate may be either a wafer in which the indium-based semiconductor material is an epitaxial layer grown on another material (e.g. silicon) or a wafer the bulk of which is formed by the indium-based semiconductor material. In many implementations the substrate will have a substantially circular perimeter, e.g. where the substrate is formed as a disc-shaped wafer. In these cases the perimeter may not be exactly circular—for example, the wafer could have the shape of a circle with one or more segments removed along a portion of it perimeter to define a corresponding number of “flats” (i.e. substantially straight sections of the perimeter), which may be used to orient the substrate and/or convey information about the composition of the substrate.

“Substrate support structure” here refers to apparatus inside the plasma processing chamber that supports and restrains the substrate mounted thereon during processing. An example of a substrate support structure suitable for this context is an electrostatic clamp (also known as an electrostatic chuck), which comprises a substrate table to the surface of which a direct current (DC) bias voltage is applied at least while the substrate is being etched. The bias voltage polarises the substrate on the substrate table, resulting in an electrostatic attraction between the substrate and table which restrains the substrate during processing. By “directly mounted”, we mean that the substrate is directly in contact with the substrate support structure and restrained by it. This is in contrast with carrier-based processes of the kind described above, where the carrier wafer on which the substrate to be etched sits is typically mounted on a substrate support structure (e.g. a mechanical clamp) while the substrate itself lies on the carrier wafer and is unrestrained. Directly mounting the substrate on the substrate support structure is highly desirable in production-scale processes since, as described above, this allows the substrates to be robotically mounted and removed under vacuum, which allows multiple substrates to be etched in sequence without delaying the processing by breaking and then restoring vacuum conditions (e.g. the vacuum inside a load lock used to introduce substrates to the chamber) between each etch as is typically required in carrier-based processes. Furthermore, the physical conditions in the vicinity of the substrate, in particular the substrate temperature, can be controlled with greater reliability and precision in processes where the substrate is directly mounted (rather than on a carrier wafer), which makes these processes particularly suitable for production-scale processes, where consistency of the manufactured devices is an important concern. As will be illustrated below with reference to an example, the substrate support structure (particularly where the substrate support structure is an electrostatic clamp) may comprise a raised portion that is raised relative to a surrounding surface of the substrate support structure and on which the substrate is disposed when mounted on the substrate support structure. This raised portion could be integral with the surrounding surface of the substrate support structure or formed by a separate supporting element (sometimes referred to as a “puck”) that is placed on that surface. Importantly, this supporting element or puck nonetheless forms part of the substrate support structure since the substrate disposed on it will still be restrained by the substrate support structure—for example, in the case of an electrostatic clamp, the puck could be biased to provide the electrostatic force that restrains the substrate mounted directly on it.

A particular problem that has been encountered when etching indium-based semiconductor materials in processes that do not employ a carrier wafer is that the resulting devices often contain deep microtrenches at the bases of etched vertical features (e.g. the walls of trenches and mesas). The term “microtrench” refers to grooves that appear at the bases of the walls of etched features and extend deeper into the substrate than the notional base of the etched feature—examples of prominent microtrenches are shown in FIG. 4(b), which will be described below. The presence of microtrenches often prevents the device in which they appear from functioning altogether. These defects usually do not arise in comparable carrier-based processes, however. The inventors have realised that the presence of silicon in the carrier-based processes described above promotes desirable characteristics in the profiles of features etched into indium-based semiconductor materials. Without wishing to be bound by theory, it is believed that silicon-containing species (e.g. radicals and ions containing silicon) produced by the chemical interaction of etchants (e.g. chlorine) in the plasma with the silicon carrier wafer contribute to passivation and reduce microtrenching.

In the method of the invention, a directly mounted substrate is etched inside a plasma processing chamber that contains solid silicon that is exposed to the plasma. The solid silicon interacts with the plasma generated inside the chamber to produce gaseous silicon-containing species, which contribute to passivation and prevention of micro-trenching. The inventors have found that devices of at least equal quality to those previously attainable only by carrier-based processes can be fabricated where the surface area of solid silicon exposed to the plasma (the “exposed surface area” defined above) is at least 1 times that of the portion of the substrate surface to be etched that is not covered by the patterned mask (which forms the area of the surface to be etched that will be exposed to the generated plasma). The fraction of this surface that is not covered by the patterned mask often varies depending on the nature of the devices being manufactured, but is typically between 10% and 90%. The present invention therefore enables consistent, production-scale manufacture of devices from indium-based semiconductor materials.

By “solid silicon” we mean elemental silicon (Si) in the solid state. The solid silicon may be provided in a variety of forms—for example as one or more wafers, slices or fragments, or preferably as a replaceable element engineered for implementations of the present invention, examples of which will be discussed below. Preferred forms for the solid silicon contained in the plasma processing chamber will be described below. It will be appreciated that the “exposed surface area” of the solid silicon defined above is not necessarily a single contiguous region and may include multiple, discrete regions. For example, the solid silicon could be provided as several unconnected sections which are spaced from one another. The “exposed surface” in that example could include all of the parts of the surfaces of the several fragments that are exposed to the plasma generated inside the plasma processing chamber.

Several iterations of the steps of the method above may be performed while continuously maintaining a vacuum or partial vacuum (e.g. a pressure in the range of 1-10 mTorr) inside the plasma processing chamber. In these processes, the plasma is quenched after etching the substrate, which is them removed. A new substrate is then mounted on the substrate support structure in the next iteration of the “mounting” step. After mounting the new substrate, the steps of establishing a flow of the etch gas mixture into the chamber and generating the plasma are repeated while the new substrate mounted on the substrate support structure. Mounting the substrate, or each substrate, may comprise transporting the substrate from a cassette inside a loadlock adjacent to the plasma processing chamber to the substrate support structure.

In preferred embodiments, the exposed surface area of the solid silicon is at least 3 times, preferably at least 6.5 times, more preferably at least 13 times, that of the area of the surface of the substrate carrying the patterned mask which is not covered by the patterned mask. As explained above, the beneficial effects of the solid silicon inside the chamber are believed to be a result of silicon-containing species generated by the interaction of the plasma with the solid silicon. The rate at which such species are generated increases in proportion to the exposed surface area of the solid silicon, so it is preferable that the exposed area is large relative to that of the surface to be etched.

As noted above, the exposed surface area of the solid silicon being at least 1 times the area of the surface to be etched which is not covered by the mask achieves a rate of silicon-containing species that is sufficient for preventing the formation of microtrenches. An increased rate of generation of silicon-containing species can be achieved by selecting the exposed surface area of the solid silicon so that it is at least 1 times the area of the surface on which the mask is carried (rather than at least 1 times only the area of the fraction of this surface that is not covered by the mask), preferably at least 3 times, more preferably at least 6.5 times.

Advantageously the solid silicon may be disposed on, or laterally adjacent to, the substrate support structure. For example, if the substrate support structure were an electrostatic clamp comprising a substrate table on which the substrate is placed in use, the solid silicon could be disposed on the substrate table adjacent to the substrate (in which case it would be disposed on the substrate support structure). Alternatively, the solid silicon could be held in place laterally adjacent to the substrate support structure by a separate structure adapted for that purpose. The “lateral” arrangement of the solid silicon here refers to the positioning of the solid silicon in the plane parallel to the surface of the substrate on which the mask is carried. Positioning the solid silicon on the substrate support structure, or at least laterally adjacent to it, helps to ensure that the exposed area of the solid silicon is relatively close to the substrate and thus encourages production of silicon-containing species near the surface to be etched.

The solid silicon preferably has a thickness of at least 1 mm, preferably at least 3 mm, in the direction perpendicular to the surface of the substrate carrying the mask when mounted on the substrate support structure. The silicon will be etched by the plasma (since silicon-containing species are generated from it), so selecting a suitable minimum thickness of the silicon in the direction along which the etching predominantly takes place (i.e. normal to the surface to be etched) ensures that the silicon does not need to be frequently replaced. In some implementations the temperature of the solid silicon may be controlled, for example by mounting the solid silicon on the substrate support structure (in cases where the substrate support structure is temperature-controlled) or by the provision of separate temperature control means for the solid silicon. The rate of production of silicon-containing species may be enhanced by applying a bias (e.g. the RF bias) to the solid silicon during the etching and/or moderated by placing electrically insulating material between the solid silicon and the substrate support structure (thereby reducing the bias to which the solid silicon is subjected, particularly where the solid silicon is disposed on the substrate support structure).

In preferred embodiments, the solid silicon laterally surrounds at least a portion, preferably all, of the perimeter of the surface of the substrate carrying the patterned mask. For example, if the solid silicon were shaped as an annulus (for example a disc having a circular central opening through its centre) and arranged such that the substrate were laterally inside the central opening of the annulus, the solid silicon would laterally surround all of the perimeter of the surface carrying the mask. If the solid silicon were in the form of a segment of such an annulus (for example having roughly a ‘C’ shape), then it would laterally surround a portion of the perimeter of the surface of the substrate carrying the patterned mask. Arranging the solid silicon so as to surround laterally (at least a portion of) the perimeter of the surface to be etched promotes uniformity in the concentration of silicon-containing species across the surface to be etched, thereby encouraging the consistent formation of features free of microtrenches across the entire surface.

Preferably the solid silicon is shaped to define an opening through the solid silicon, wherein the substrate mounted on the substrate support structure is laterally inside the opening. The example of an annulus just described would provide this feature, with the substrate arranged laterally inside the central opening of the annulus. Hence, as described above, the solid silicon preferably forms an annulus, preferably an annular disc, which defines the opening. Solid silicon having an annular form is particularly suitable where the substrate to be etched has a circular shape, in which case the dimensions of the annular solid silicon may be chosen so as to minimise the lateral separation between the surface carrying the mask and the edge of the inner opening of the annulus. An annular disc is a particularly preferred form.

In some particularly preferred embodiments, the solid silicon is electrically isolated from the substrate support structure and, when the substrate is mounted on the substrate support structure, from the substrate. This provides a very significant advantage due to the fact that it reduces coupling of the RF bias that is applied to the substrate support structure into the solid silicon, which ensures that the RF bias signal is concentrated in the area of the substrate. This in turn ensures that the power density of the RF bias signal is concentrated in the area of the substrate and thereby promotes a high rate of etching. Preferably, the electrical isolation is provided by an electrically insulating element arranged between the solid silicon and the substrate support structure so as to space the solid silicon from the substrate support structure and the substrate when mounted on the substrate support structure. An electrically insulating element arranged in this manner ensures that the solid silicon is not in contact with the substrate support structure or the substrate, which reduces the RF bias signal transmitted into the solid silicon.

Where the electrically insulating element just described is present, preferably the electrically insulating element and the solid silicon are arranged such that a surface of the solid silicon exposed to the plasma is at a height of 0-5 mm, preferably 0-3 mm, more preferably 1.5-2 mm, above the surface of the substrate on which the patterned mask is carried, along the direction perpendicular to said surface of the substrate. This has been found to achieve good electrical isolation of the solid silicon while keeping the solid silicon in proximity to the wafer and achieving unform etching of the wafer.

Advantageously, the electrically insulating element is disposed on the substrate support structure such that it lies laterally adjacent to the substrate when the substrate is mounted on the substrate support structure, and wherein the solid silicon is supported by the electrically insulating element. For example, the electrically insulating element could be formed by a ring of electrically insulating material with a sufficient diameter that it can be disposed on the substrate support structure concentric with the substrate. The solid silicon can then be supported on the electrically insulating element, whereby it will be spaced from the substrate support structure. Therefore, preferably, the solid silicon has a central aperture arranged so as to be concentric with the substrate when the substrate is mounted on the substrate support structure; and wherein the electrically insulating element is arranged to prevent the plasma passing into the space between the solid silicon and the substrate support structure via the central aperture. In these embodiments, the electrically insulating element may have the ring shape just described (or, in more general terms, an annular form), so preferably the electrically insulating element has an annular form and is arranged so as to be concentric with the substrate when the substrate is mounted on the substrate support structure.

The electrically insulating element is preferably made of a dielectric material, preferably quartz. However, the electrically insulating element could be made of any material(s) arranged to provide the required electrical isolation of the solid silicon.

As noted above, it is advantageous to ensure that the exposed solid silicon is in close proximity to the surface to be etched. Therefore, preferably, each part of the perimeter of the surface on which the mask is carried is laterally spaced from the exposed surface of the solid silicon by no more than 5 mm, preferably no more than 1 mm. As noted above and as will be discussed below, the solid silicon and the substrate may laterally overlap one another in some particularly preferred embodiments, where the substrate overhangs the edge of a raised portion of the substrate support structure on which it is disposed when mounted on the substrate support structure. In these embodiments, the lateral spacing of the perimeter of the substrate from the solid silicon is zero since the perimeter of the substrate laterally overlaps the solid silicon.

In preferred embodiments, the solid silicon forms a substantially planar surface that is exposed to the generated plasma. The substantially planar surface may form a part or substantially all of the exposed surface area of the solid silicon. The exposed surface being arranged with a planar form promotes uniform, predictable transport of the generated silicon-containing species away from the exposed surface since it limits the influence of the shape of the surface on the dynamic behavior of the plasma in its vicinity. The solid silicon could also or alternatively define a textured surface that is exposed to the plasma. Such a textured surface may be provided in order to increase the exposed surface area formed by the silicon within a given perimeter.

Preferably, the solid silicon forms a surface that is oriented substantially parallel to the surface of the substrate carrying the patterned mask and is exposed to the generated plasma. This promotes uniform delivery of the generated silicon-containing species to the surface to be etched. This feature is particularly advantageous where the solid silicon is disposed on, or laterally adjacent to, the substrate support structure and/or where the substrate is positioned laterally inside an opening in the solid silicon as described above.

The solid silicon may form a surface that is arranged substantially in the plane of the surface of the substrate on which the mask is carried and is exposed to the generated plasma. For example, if the substrate were arranged laterally inside an opening in the solid silicon as described above, this feature could be provided by positioning the silicon along the direction parallel to the substrate surface to be etched such that at least a part of the exposed surface of the solid silicon is in the same plane as that surface of the substrate. Alternatively, the exposed silicon surface may be arranged so that it does not meet or intersect the plane of the surface on which the mask is carried—this may be the case in some preferred embodiments described below, in which the substrate support structure comprises a raised portion on which the substrate is disposed when mounted on the substrate support structure.

In preferred embodiments, the surface of the substrate on which the mask is carried has a smallest lateral dimension of at least 50 millimetres (mm), preferably at least 100 mm. The surface on which the mask is carried is the surface formed by the indium-based semiconductor material, as defined above. By “smallest lateral dimension” we mean the smallest dimension of this surface along any direction. In many cases the surface on which the mask is carried will have a circular perimeter, in which case its smallest lateral dimension is simply the diameter. If the perimeter of the surface were elliptical, the smallest lateral direction would be the minor axis of the ellipse. If it were oblong, the smallest lateral dimension would be the shorter side length of the oblong.

Preferably the surface of the substrate on which the mask is carried has a surface area of at least 2000 millimetres squared (mm²), preferably at least 4000 mm². For example, the surface formed by one side of a circular wafer with a 76 mm diameter will have an area of about 4536.5 mm². Substrates providing surfaces with areas in these ranges are preferred for industrial scales of production in particular.

Processes for etching indium-based semiconductor materials, in particular InP, are often conducted as “hot” processes, in which the material being etched is deliberately heated above the ambient temperature (and often very substantially above the ambient temperature, e.g. by tens or hundreds of degrees Celsius). While the plasma to which the substrate is exposed typically causes it to heat, it can be advantageous to supply additional heat by heating the substrate support structure on which the substrate is mounted. Hence, the method may advantageously comprise controlling the temperature of the substrate support structure during the etching, preferably such that the temperature of the substrate remains in the range of 100 to 300 degrees Celsius, preferably 150 to 250 degrees, more preferably 180 to 220 degrees, during the etching. In the present method, the substrate is mounted directly on the substrate support structure, which allows the substrate to be heated much more rapidly, efficiently and with greater reliability than in processes where a carrier wafer is present between the substrate and the support structure. A significant advantage of the present invention over carrier-based processes stems from the fact that the substrate is directly mounted on the substrate support structure. This direct mounting means that the substrate can be heated by the substrate support structure independently of the silicon, whereas in a carrier-based process, where the solid silicon is between the substrate support structure and the substrate being etched, heating the substrate inevitably requires heating the silicon. Whereas it is desirable that the substrate support structure and substrate are not heated above the upper limits of the ranges above (particularly electrostatic clamps, to which excessive heating can be damaging), it may be desirable for the solid silicon to reach higher temperatures in order to promote effective production of silicon-containing species. The present invention allows the temperature of the solid silicon to be decoupled from that of the substrate and the substrate support structure, since the silicon may be allowed to be heated by the plasma to high temperatures while the temperature of the substrate support structure is controlled within a desired range.

In particularly preferred embodiments, the method comprises supplying a heat transfer gas, preferably helium, between the substrate and the substrate support during the etching, so as to control the temperature of the substrate. The heat transfer gas can transfer heat from the substrate support structure to the substrate, but also prevents excessive heating of the substrate by removing heat from it when it is heated by the plasma above the temperature of the substrate support structure. This is particularly advantageous where the substrate support structure is an electrostatic clamp, since, while it is advantageous to heat the substrate for the reasons noted above, such clamps can be damaged when subject to excessively high temperatures over prolonged time periods.

Where a heat transfer gas is utilised as described above, preferably the pressure of the heat transfer gas where it contacts the substrate is in the range of 1-20 Torr, preferably 3-15 Torr, more preferably 5-10 Torr. These ranges have been found to provide suitable rates of heat transport into and away from the substrate.

Preferably the substrate support structure is an electrostatic clamp. As noted above, electrostatic clamps are particularly preferred since they are capable of supporting and retaining the substrate in position without covering any part of the surface on which the mask is carried, thereby maximising the usable area of the substrate surface. An example of an alternative substrate support structure is a mechanical clamp.

The substrate support structure may comprise a raised portion which is raised relative to a surrounding surface of the substrate support structure, wherein the substrate is disposed on the raised portion when mounted on the substrate support structure. As noted above, the raised portion could be integral with the surrounding surface of the substrate support structure or formed by a separate supporting element (e.g. a “puck”) that allows the substrate to be directly mounted (e.g. by being configured to electrostatically clamp the substrate by features such as an electrode incorporated in the supporting element) and thereby supported and restrained on the raised portion. The separate supporting element will typically be made of the same material(s) as the surrounding surface. It will be appreciated that the supporting element and other parts of the substrate support structure cannot be made of materials that are susceptible to substantial etching by the plasma (e.g. silicon and other semiconductors) since these materials will quickly degrade if exposed to the plasma. Preferably the substrate overhangs the periphery of the raised portion, for example where the lateral dimensions of the substrate are greater than those of the raised portion. Advantageously, where the substrate is on a raised portion as described above, the solid silicon may disposed on the surrounding surface of the substrate support structure, preferably laterally overlapping the overhanging part of the substrate. This lateral overlap between the substrate and the solid silicon is advantageous as, in this configuration, the silicon and substrate can be arranged so that no part of the surface of the raised portion of the surrounding surface is exposed to the plasma during the etching. This helps to prevent damage to the substrate support structure (particularly where it is an electrostatic clamp), thereby extending its working lifetime.

Preferably the indium-based semiconductor material comprises at least 5% indium by weight. In preferred implementations the indium-based semiconductor material is indium phosphide or a ternary or quaternary alloy thereof. As noted previously, indium phosphide in particular is suitable for a wide range of applications, and the processes described herein are particularly suited for manufacturing devices from this material. However, the presence of indium in other indium-based semiconductor materials leads these materials to have similar properties (e.g. their interaction with species in the plasma and the dependence of their behavior on the physical conditions to which they are subjected during etching) to indium phosphide, as a result of which the preferred features of the methods described throughout this specification apply across the class of indium-based semiconductor materials.

The mask may comprise one or more of silicon dioxide, silicon nitride and a metal such as chromium.

The inert gas is preferably a noble gas, preferably argon (Ar). Helium (He) and xenon (Xe) are other examples of suitable noble gases. In some embodiments more than one inert gas may be present in the etch gas mixture, so the etch gas mixture could comprise two or more of helium, xenon and argon.

Preferably the chlorine-bearing gas is molecular chlorine Cl₂, boron trichloride BCl₃ or silicon tetrachloride SiCl₄. Each of these compounds is suitable for etching into InP and producing silicon-containing species in methods in accordance with the invention.

In some particularly preferred embodiments: the chlorine-containing gas is flowed into the plasma processing chamber at a rate in the range of 2-20 sccm, preferably 4-20 sccm, more preferably 5-15 sccm, and/or the inert gas is flowed into the plasma processing chamber at a rate in the range of 5-50 sccm, preferably 20-50 sccm, more preferably 20-30 sccm. Flow rates in these ranges, particularly in combination, have been found to achieve reasonable etch rates while producing features that are substantially free of microtrenches and exhibit highly vertical side walls. These preferred values apply to in particular to substrates with lateral dimensions (e.g. diameter) of up to 100 mm. In some implementations, higher flow rates may be selected for substrates of larger lateral dimensions.

Preferably the ratio of the inert gas to chlorine-bearing gas in the etch gas mixture is in the range of 1:1 to 13:1, preferably 1:1 to 5:1, preferably 2:1 to 3:1. Again, etch gas mixtures of these compositions have been found to achieve reasonable etch rates while producing features that are substantially free of microtrenches and exhibit highly vertical side walls.

The etch gas mixture may further comprise hydrogen, wherein preferably the proportion of hydrogen in the etch gas mixture by volume is no more than 25%, preferably no more than 20%. The presence of hydrogen in the etch gas mixture has been found to moderate the rate at which the solid silicon is etched by the plasma. The addition of hydrogen thus allows the rate at which silicon-containing species are generated to be controlled and hence optimised for the particular substrate and process parameters being employed.

In preferred embodiments the RF bias voltage has a power in the range of 50-250 watts (W), preferably 100-200 W. These preferred values apply to in particular to substrates with lateral dimensions (e.g. diameter) of up to 100 mm. In some implementations, higher power values may be selected for substrates of larger lateral dimensions in order to achieve power densities across the substrate similar to those achieved by applying the above preferred values to substrate of lateral dimensions below 100 mm.

Preferably, the pressure in the plasma chamber during the etching is in the range of 1-10 mTorr, preferably 1-4 mTorr. These pressure conditions may be established before the substrate is etched and maintained after it has been etched.

The plasma is preferably generated by an inductively coupled plasma source. Other types of plasma source could also be used, for example capacitively-coupled plasma sources and microwave plasma sources.

In preferred embodiments the plasma is generated with a power in the range of 500-2500 W, preferably 750-1250 W. Preferably the amplitude of the RF bias voltage is in the range of 100-250 volts (V), preferably 150-200 V.

In some particularly preferred embodiments of the invention, the indium-based semiconductor material is InP; the solid silicon is disposed on the substrate support structure, which is an electrostatic clamp; and the exposed surface area of the solid silicon is at least 13 times the area of the surface of the substrate carrying the mask which is not covered by the patterned mask. Preferably in these embodiments, the chlorine-bearing gas is Cl₂ flowed into the plasma processing chamber at a rate in the range of 5-15 sccm; the inert gas is argon flowed into the plasma processing chamber at a rate of 20-30 sccm; the pressure inside the plasma processing chamber during the etching is in the range of 1-4 millitorr (mTorr); the plasma is generated with a power in the range of 750-1500 watts (W); the amplitude of the RF bias voltage is in the range of 150-200 volts (V); the power of the RF bias voltage power is in the range of 100-200 W; the temperature of the substrate support structure is controlled to remain within the range of 180-220° C. during the etching; and a heat transfer gas is supplied between the substrate and the substrate support structure during the etching, so as to control the temperature of the substrate. These processes, particularly with the preferred process parameters just quoted, here have been found to achieve excellent results, virtually eliminating microtrenching while forming smooth, vertical side walls at good etch rates.

### BRIEF DESCRIPTION OF DRAWINGS

Examples of methods in accordance with embodiments of the invention will now be described with reference to the accompanying drawings, in which:

FIG. 1 shows an example of an apparatus suitable for using in performing methods in accordance with embodiments of the invention;

FIG. 2 shows an example of a suitable form for the solid silicon that may be used in methods in accordance with embodiments of the invention;

FIG. 3 is a flow diagram representing steps of a method in accordance with an embodiment of the invention;

FIG. 4(a) is an electron micrograph of features etched by a method in accordance with an embodiment of the invention;

FIG. 4(b) is an electron micrograph of features etched in accordance with a comparative example of a method that is not an embodiment of the invention; and

FIG. 5(a) shows a detailed view of an example of how the solid silicon and substrate may be arranged in some embodiments of the invention;

FIG. 5(b) shows a detailed view of an alternative arrangement to that of FIG. 5(a);

FIG. 6 shows a detailed view of an example of how the solid silicon and substrate may be arranged in a further embodiment of the invention;

FIG. 7 is a photograph of a substrate support structure in accordance with embodiment represented schematically in FIG. 6;

FIGS. 8(a) and 8(b) are electron micrographs showing features etched in accordance with a first experiment in accordance with an embodiment of the invention;

FIGS. 9(a) and 9(b) are electron micrographs showing features etched in accordance with a second experiment in accordance with an embodiment of the invention;

FIGS. 10(a) and 10(b) are electron micrographs showing features etched in accordance with a third experiment in accordance with an embodiment of the invention;

FIGS. 11(a) and 11(b) are electron micrographs showing features etched in accordance with a fourth experiment in accordance with an embodiment of the invention;

FIGS. 12(a) and 12(b) are electron micrographs showing features etched in accordance with a fifth experiment in accordance with an embodiment of the invention;

FIG. 13 shows a detail viewed of an exemplary implementation of the arrangement shown in FIG. 6.

### DETAILED DESCRIPTION

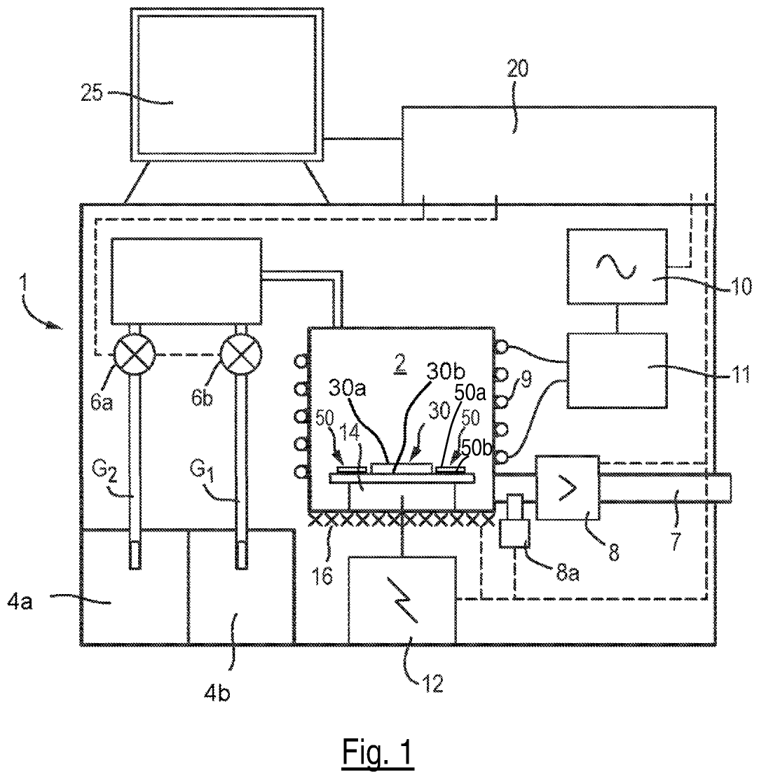

FIG. 1 shows an example of a plasma processing tool suitable for implementing the presently disclosed methods. The plasma processing tool 1 comprises a plasma processing chamber 2 within which a substrate 30 is placed during use. The substrate comprises an indium-based semiconductor material, for example indium phosphide, that forms a surface 30a of the substrate 30. The indium-based semiconductor material could be an epitaxial layer on a substrate wafer, for example. The surface 30a formed by the indium-based semiconductor material carries a patterned mask that covers parts of the surface 30a defining the features to be etched into the indium indium-based semiconductor. The parts of the surface 30a not covered by the mask are exposed to plasma generated inside the chamber 2.

To perform etching, an etch gas mixture including an inert gas (for example argon, Ar, helium, He, or xenon, Xe) and one or more chlorine-bearing gases (for example molecular chlorine, Cl₂, silicon tetrachloride, SiCl₄, or boron trichloride, BCl₃) is introduced to the plasma processing chamber 2 and the conditions inside the chamber 2 are controlled in order to effect the desired etching mechanism. The process parameters within the chamber are controlled and can be adjusted by a set of at least one (but more typically a plurality of) devices, of which examples are shown schematically in FIG. 1. In this example, the tool 1 is equipped with two input gas supplies 4(a) and 4(b) for supplying first and second input gases, G1 (e.g. Ar) and G2 (e.g. Cl₂) respectively, to the plasma processing chamber 2. Some embodiments of the invention employ etch gas mixtures comprising more than two gases, and it will be understood that the plasma processing tool 1 may have any number of gas supplies each configured to supply a respective one of the component gases of the etch gas mixture. For example, a third gas supply could be configured to supply hydrogen (H₂). The ingress of each gas to the chamber 2 is controlled by valves 6(a) and 6(b) and respective mass flow controllers (not shown). Again, additional mass flow controllers may be provided where more than two gases are comprised by the etch gas mixture. The exhaust gas, including unreacted input gases and any reaction products, is removed from plasma processing chamber 2 via a duct 7 and associated pump(s) 8, the pump(s) 8 typically being capable of reducing the pressure within the chamber to near-vacuum conditions. The chamber pressure will be determined in the main part by the exhaust pump system and particularly the pumping speed and the “conductance” of the pumping line from the chamber to the pump (this is a factor related to the geometry of the pumping line). However during processing, when a plasma is created and/or when etching takes place, gaseous species may be lost or created inside the chamber thereby having an effect on the pressure. In order to regulate for such variation, an automatic pressure control valve 8a is preferably provided as known in the art. The valve 8a changes the conductance of the pumping line to thereby enable the chamber pressure to be maintained substantially constant at the desired level as the plasma is struck and the material etched.

The plasma processing tool 1 is equipped with a plasma source for generating a plasma within the plasma processing chamber by means of an electrical discharge. Here, the plasma source is depicted as an inductively-coupled plasma source comprising a coil 9 surrounding the plasma processing chamber 2, which is supplied with RF power from power supply 10 via a RF matching unit 11. The RF matching unit 11 is configured to match the plasma impedance to that of the RF supply 10 in order to maximise efficiency of power transfer from the supply to the plasma. An example of a suitable matching unit is disclosed in WO-A2010/073006. Other types of plasma source such as a capacitively-coupled plasma (CCP) or a microwave plasma source could be used instead.

The substrate 30 is mounted directly on a substrate support structure 14, which supports and restrains the substrate 30 in position during etching. The substrate support structure 14 is preferably an electrostatic clamp, but other substrate support structures, for example a mechanical clamp, could be used. The use of an electrostatic clamp is particularly advantageous in the context of industrial-scale processes, since these devices are capable of securely retaining the substrate in place without covering any part of the surface to be etched, thereby maximising the usable area of the substrate surface. The plasma processing chamber 2 may contain a robotic tool (not shown) configured to mount and remove substrates (e.g. wafers) from the substrate support structure 14 while a vacuum or partial vacuum is sustained inside the plasma processing chamber 2. The provision of such a tool allows multiple substrates to be processed in sequence without needing to break and then re-establish vacuum conditions each time a new substrate is to be etched, thus increasing the rate at which the substrates can be processed. The substrates retrieved by the robotic tool could be stored in a cassette, which could be inside a loadlock adjacent to the plasma processing chamber 2. The processed substrates could be placed in a separate cassette by the robotic tool once removed from the substrate support structure 14.

A bias voltage is applied in use to the substrate 30. This is achieved by connecting a voltage source 12 to the substrate support structure 14. The bias voltage in this example is a radio frequency (RF) voltage, which typically will have a frequency of about 13.56 MHz. If an RF power supply 12 is used then an Automatic impedance Matching Unit (AMU) may preferably be provided to ensure good coupling of power from the power supply 12 to the substrate support structure 14. Where the substrate support structure 14 is an electrostatic clamp, the bias applied to generate an electrostatic force between the substrate 30 and the substrate support structure 14 is distinct from, and provided in addition to, the RF bias voltage, the purpose of which is to promote anisotropic etching of the indium-based semiconductor material in the direction perpendicular to the surface being etched.

The plasma processing chamber 2 contains solid silicon 50. As noted above, by “solid silicon” we mean elemental silicon, Si, in the solid state, which will typically have the form of one or more crystals machined or otherwise manufactured into the desired shape. In this example, the solid silicon 50 forms an annular element that is disposed on the substrate support structure 14 concentrically with the substrate 30. Part of the surface of the solid silicon 50, including the side 50a that is distal to the substrate support structure 14, is exposed to plasma generated inside the chamber. The surface 50b proximal to the substrate support structure 14 is not exposed to the generated plasma in this case, since here this surface 50b is in contact with the substrate support structure 14 and cannot be reached by the generated plasma. The effects of the solid silicon 50 on the etching of the substrate 30 will be discussed in more detail below.

In methods in accordance with the invention, the exposed surface area of the solid silicon is at least 1 times the area of the surface of the substrate carrying the patterned mask which is not covered by the patterned mask. An example of calculating the exposed ratio of exposed surface area of the solid silicon to the area of the surface carrying the mask (which is the surface to be etched) which is not covered by the mask will now be described. In this example, the substrate is formed as a circular wafer with a diameter of 76 mm, with the surface to be etched forming one side of the wafer and the patterned mask being carried on that side. The surface carrying the mask has a total surface area of π(0.5*76 mm) 2=4536.5 mm². The patterned mask covers 50% of the area of the surface to be etched, so the area of the surface carrying the mask which is not covered by the mask is about 2268.2 mm². The solid silicon could be provided in the form of an annular disc as just described, with an outer diameter of 100 mm and an inner diameter (i.e. the diameter of the central opening) being about 76 mm, matching the diameter of the substrate. The exposed surface area provided by this form of the solid silicon when placed on the substrate support structure (so that one side of the disc is exposed) is about 3317 mm². The exposed area of the solid silicon in this example is therefore about 1.4 times the area of the surface of the substrate carrying the mask which is not covered by the mask.

The tool 1 may further comprise a temperature control unit 16 such as a heater and/or cooling system for adjusting the processing temperature of the substrate support structure 14 (additional devices for heating and/or cooling of the plasma processing chamber and plasma source may be provided to assist with process control and/or to maintain hardware stability). The temperature control unit 16 may additionally be configured to deliver a heat transfer gas such as helium to the substrate 30, for example to the surface 30b of the substrate 30 proximal to the substrate support structure 14. The provision of a heat transfer gas offers improved control over the heating and cooling of the substrate and increases the speed at which heat transfers between the substrate 30 and the substrate support structure 14.

The devices operate upon instruction from a controller 20, such as a programmable logic controller (PLC) or similar. In some cases, more than one controller can be provided, with each controller controlling one or a subset of the devices. The controller is also connected to a user interface device such as a computer workstation 25 for receiving input from the user and/or returning outputs.

In FIG. 1, the data connections between the various devices and the controller 20 are indicated by dashed lines. In practice, this may be implemented as a network such as a CANbus bridge, which has connections to each of the devices as well as the user interface 25. The bus typically comprises multiple network channels including one or more data channels such as serial data channels (e.g. RS485) and, optionally, one or more power channels. The controller 20 issues commands across the bus, each of which is addressed to one or more of the devices and includes instructions as to one or more process parameters the device in question is to implement. An example of a network protocol which could be used for the issuing of commands for the control of the devices is given in WOA-2010/100425. Of course, many other network implementations are possible as will be appreciated by the skilled person.

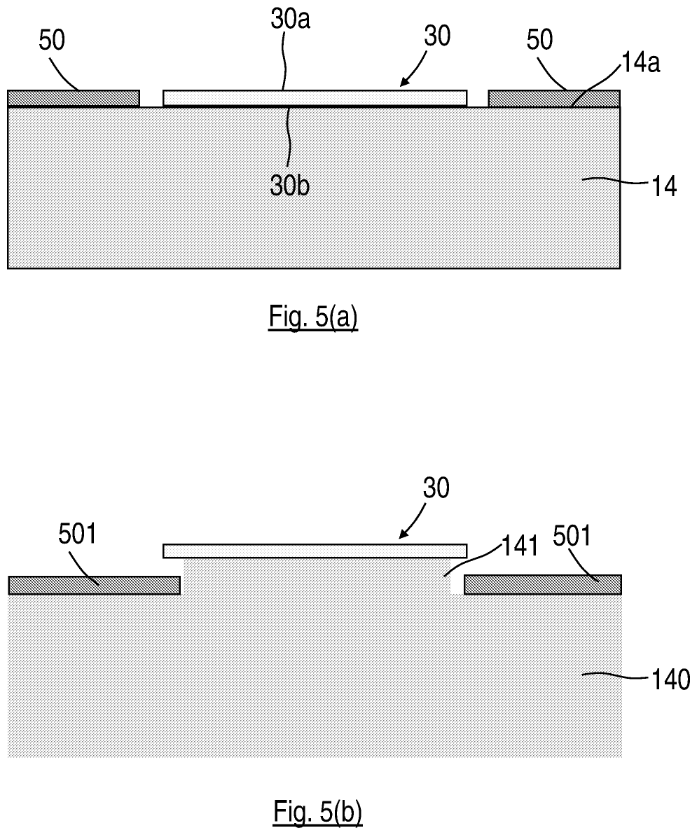

FIG. 5(a) shows a detailed view of the substrate support structure 14 of FIG. 1. The substrate 30 is arranged on a flat surface 14a of the substrate support structure and is in the same plane as the silicon 50, which is disposed on the same surface laterally adjacent to the substrate (in this case concentric with it, since the silicon 50 has an annular form). In this example there is a slight lateral separation between the solid silicon 50 and the perimeter of the substrate 30, which is preferably less than 5 mm, more preferably less than 1 mm.

FIG. 5(b) shows a detailed view of an alternative substrate support structure 140 on which the substrate 30 could be arranged in preferred embodiments. The substrate support structure 140 includes a raised portion 141 on which the substrate 30 is disposed. The lateral extent of the raised portion 141 is less than that of the substrate 30, so the outer parts of the substrate 30 overhang the periphery of the raised portion 141. The solid silicon 501 has an annular form similar to that described above with reference to FIGS. 1 and 5(a) and is arranged concentrically with the substrate 30 and the raised portion on the surface of the substrate support structure 140 surrounding the raised portion. The diameter of the central opening of the annular solid silicon 501 in this case is less than the lateral width of the substrate 30, however, so the overhanging parts of the substrate 30 laterally overlap the parts of the solid silicon 501 near the raised portion 141. This arrangement is advantageous as the surface of the substrate support structure 140 is substantially wholly covered by the substrate 30 and the solid silicon 501. The raised portion 141 in this example is integral with the surrounding surface of the substrate support structure 140, but could alternatively be provided as a separate supporting element (e.g. a puck).

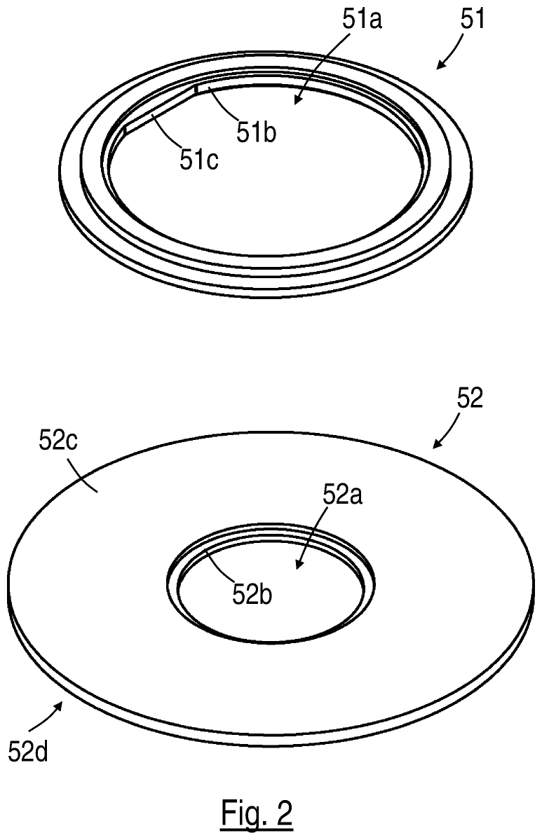

FIG. 2 shows an example of a suitable form in which the solid silicon may be provided in implementations of the invention. The solid silicon comprises two annular elements: an inner element 51 and an outer element 52, both formed of solid silicon. The annular inner element 51 defines a central opening 51a and in use is preferably placed on a substrate support structure (such as the support structure 14 described above) concentrically with a circular substrate in the orientation shown. In preferred embodiments of methods in which this element is used, the diameter of the central opening 51a is such that all parts of the perimeter of the surface of the substrate to be etched are laterally spaced from the perimeter 51b of the central opening 51a by no more than 10 mm, preferably no more than 5 mm. The substrate could be a circular wafer with a diameter of four inches, for example, in which case the diameter of the central opening 51a could be greater than four inches by less than 10 mm, preferably less than 5 mm. The inner element 51 has a stepped profile. The perimeter 51b of the central opening 51a is substantially circular but defines a flat section 51c, which corresponds in form to a removed segment of the circle.

The outer element 52 also has an annular shape with a central opening 52a. The perimeter 51b of the central opening 52a has a stepped profile shaped to cooperate with the stepped profile of the inner element 51. In use, the outer element 52 will be placed over the inner element 51 such that stepped profile of the inner element 51 cooperates with the profile of the central opening 52a of the outer element 52. The surface 52c shown, which is a lower surface of the element 52, will thus lie facing the substrate support structure or other surface on which the inner element 51 is disposed, with the reverse surface 52d (not visible), which forms an upper surface of the element, being exposed to the plasma. The reverse side has the same planar form as the lower surface 52c shown. In this case, the majority of the exposed surface area of the solid silicon is formed by the exposed surface of the outer element 52. The reverse surface 52d therefore preferably has a surface area of at least 1 times the area of the surface of the substrate carrying the mask which is not covered by the patterned mask in embodiments in which this element is employed. When the inner element 51 and outer element 52 are placed concentrically with a substrate inside the central openings 51a, 52a thereof, the solid silicon laterally surrounds the perimeter of the substrate and the substrate is laterally inside the openings. When placed on substrate support structure together with a planar (e.g. disc-shaped) substrate in the manner shown in FIG. 1, the upper surface 52d of the outer element 52 forms a surface that is oriented parallel to the surface of the substrate on which the patterned mask is carried and is exposed to plasma generated inside the plasma chamber.

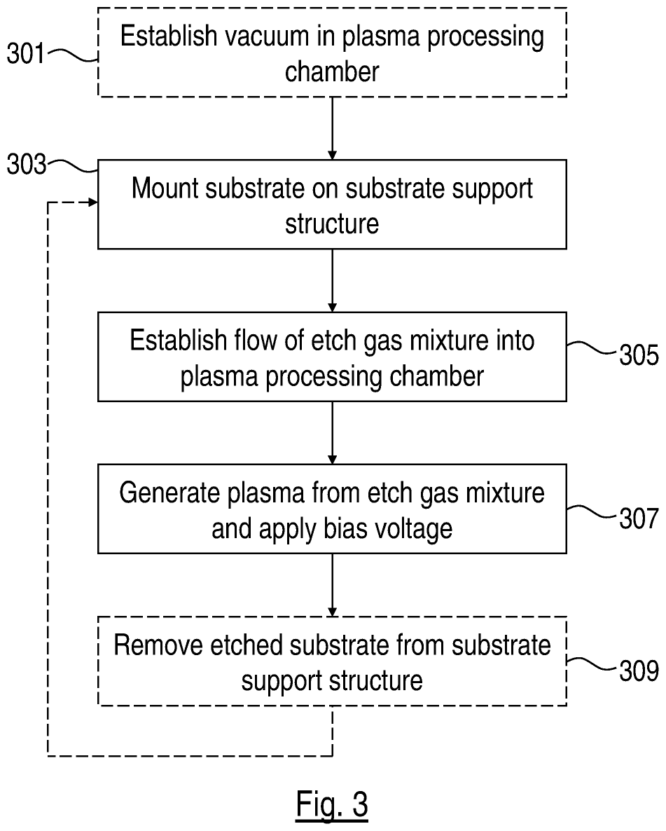

FIG. 3 is a flow diagram representing steps of a method in accordance with an embodiment of the invention. This method may be performed using the apparatus described above with reference to FIG. 1. At step 303, a substrate is mounted directly on (i.e. such that it is in contact with and restrained by) a substrate support structure such as the electrostatic clamp described above with reference to FIG. 1. The substrate comprises an indium-based semiconductor material, typically comprising at least 5% indium by weight, which forms a surface of the substrate that carries a patterned mask defining the features to be etched. As noted previously, examples of indium-based semiconductor materials include indium phosphide (InP) and ternary and quaternary alloys thereof. The mask could be a layer of silicon dioxide (SiO₂) deposited on the indium-based semiconductor material surface in accordance with the required pattern, for example. The surface on which the mask is carried preferably has a smallest lateral dimension of at least 50 mm, more preferably at least 100 mm and/or an surface area of at least 2000 mm², preferably at least 4000 mm².

Solid silicon is present inside the plasma processing chamber and is exposed to plasma generated inside the chamber, and the exposed surface area is at least 1 times the area of the surface on which the mask is carried which is not covered by the patterned mask (but preferably much greater, for example at least 3, 6.5 or 13 times the area of this part of the surface carrying the mask). The solid silicon may be disposed on the substrate support structure, for example as shown in FIG. 1, or laterally adjacent to it, e.g. being mounted in a separate clamp adjacent to the substrate support structure. The solid silicon elements described above with reference to FIG. 2 are a suitable form for the solid silicon and can be placed concentrically with the substrate as shown in FIG. 1.

At step 305, a flow of an etch gas mixture is flowed into the plasma processing chamber. The etch gas mixture includes at least an inert gas (e.g. argon) and a chlorine-bearing gas (e.g. molecular chlorine, Cl₂) configured to release chlorine radicals into a plasma generated from the etch gas mixture. Advantageously the chlorine-bearing gas is flowed into the plasma processing chamber at a flow rate in the range of 2-20 sccm, preferably 4-20 sccm, more preferably 5-15 sccm and the inert gas is flowed into the plasma processing chamber at the rate in the range of 5-50 sccm, preferably 20-50 sccm, more preferably 20-30 sccm. The etch gas mixture may also comprise hydrogen, preferably at a concentration of no more 25%, more preferably no more than 20%, of the etch gas mixture by volume. As discussed above, the provision of hydrogen moderates the rate at which the solid silicon is etched and thus affords control over the rate of production of silicon-containing species in the plasma to be generated.

At step 307, a plasma is generated from the etch gas mixture, preferably with a power of 500-2500 W, more preferably 750-1250 W. As at least part of the surface of the solid silicon inside the plasma processing chamber is exposed to the plasma, silicon-containing species are generated from the solid silicon and enter the plasma. Simultaneously, a radio frequency (RF) bias, preferably having a power in the range of 50-250 W, more preferably 100-200 W, is applied to the substrate support structure. The RF bias preferably has an amplitude in the range of 100-250 V, preferably 150-200 V. The plasma etches into the indium-based semiconductor material that is not covered by the patterned mask, thereby forming etched features in the indium-based semiconductor material. Preferably the plasma processing chamber is under partial vacuum conditions during the etching, preferably with a pressure in the range of 1-10 mTorr, preferably 1-4 mTorr. At least during the etching, it is preferable that the temperature of the substrate support structure is controlled such that it remains in the range of 100 to 300 degrees Celsius (° C.), preferably 150 to 250° C., more preferably 180 to 220° C. The temperature of the solid silicon is typically not controlled, however, and may reach temperatures above the upper limits of these ranges due to heating by the plasma. In order to control the temperature of the substrate, a heat transfer gas such as helium may be supplied between the substrate support structure and the substrate, preferably such that the pressure of the heat transfer gas where it contacts the substrate (often referred to as the “backside pressure”) is in the range of 1-20 Torr, preferably 3-15 Torr, more preferably 5-10 Torr. The plasma may be quenched after the etching has been completed in step 307.

In some embodiments, particularly those in which the method implements an industrial-scale production process, several substrates may be etched in sequence while a (partial) vacuum inside is continuously sustained inside the plasma processing chamber. The method may therefore include, at step 301, establishing a vacuum inside the plasma processing chamber before mounting the substrate on the substrate support structure in step 303. Then, after the substrate has been etched in step 307, the etched substrate may be removed from the substrate support structure in step 309 and a new substrate mounted on the substrate support structure and then etched in a further iteration of steps 303, 305 and 307. Steps 301 and 309 and the additional iteration(s) of steps 303, 305 and 307 are optional, as indicated by the dashed lines in FIG. 3. The plasma may be quenched between after the etching has been completed in each iteration of step 307 before proceeding to step 309.

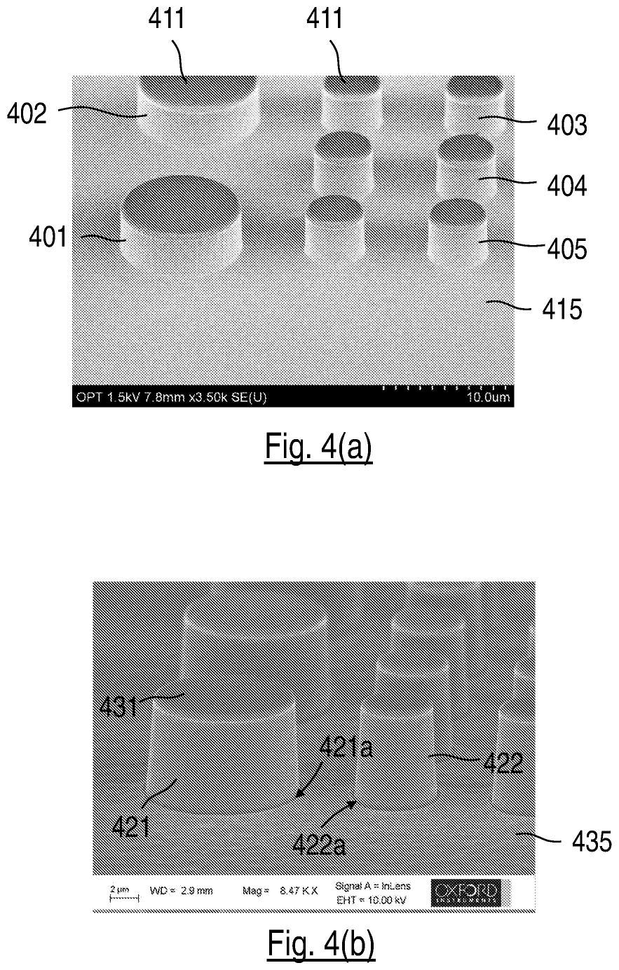

FIG. 4(a) is an electron micrograph showing indium phosphide 415 etched by a method in accordance with an embodiment of the invention. The indium phosphide etched was provided as a circular wafer with a diameter of about three inches (76 mm). The surface of the InP shown carried a patterned mask 411 of SiO₂. The features etched into the indium phosphide in this example are cylindrical mesas 401, 402, 403, 404, 405 defined by a silicon dioxide (SiO₂) mask 411. In the region shown, the patterned mask forms a number of circular elements which define the lateral form of the etched mesas. The plasma used to perform the etching was generated from an etch gas mixture containing molecular chlorine (Cl₂) and argon (Ar). An inductively coupled plasma source was used to generate the plasma. The substrate in which the etched InP shown in FIG. 4(a) is incorporated was mounted directly on an electrostatic clamp, which was heated. An RF bias was applied to the surface of the electrostatic clamp on which the substrate was mounted during the etching. Helium was supplied to the surface of the substrate proximal to the electrostatic clamp in order to control the temperature of the substrate during the etching. Solid silicon was provided on the electrostatic clamp adjacent to the wafer. The surface area of the solid silicon exposed to the wafer was approximately 31,000 mm², which is about 6.8 times the area of the surface of the InP on which the mask 411 was carried prior to the etching. About 50% of the surface on which the mask was carried was not covered by the mask, so in this example the exposed area of the solid silicon was about 13.6 times the area of the surface carrying the mask which was not covered by the mask.

FIG. 4(b) is an electron micrograph showing indium phosphide 435 etched by a method in accordance with a comparative example of a method not within the scope of the invention (due to the absence of solid silicon exposed to the plasma), in which the process parameters, etch gas composition and the mask 431 carried on the surface of the InP were the same as those as the method used to etch the indium phosphide shown in FIG. 4(a). Again, the InP was provided as a circular wafer with 3 inches (76 mm) diameter and a patterned SiO₂ mask covering approximately 50% of the InP surface. The process used to etch the material shown in FIG. 4(b) differed from that of the FIG. 4(a) example in that the plasma processing chamber did not contain any solid silicon exposed to the plasma. In place of the silicon used in the FIG. 4(a) example, a quartz ring of comparable surface area was placed on the substrate support structure adjacent to the substrate.

The process parameters under which the substrates of FIGS. 4(a) and 4(b) were etched are listed in Table 1 below. The parameters listed are, in the order in which they appear in Table 1: the flow rate of Cl₂ in standard cubic centimetres per minute (sccm); the flow rate of Ar, in sccm; the pressure inside the plasma processing chamber, in millitorr (mTorr); the plasma source power, in watts (W); the RF bias voltage applied to the electrostatic clamp, in volts (V); the power of the RF bias voltage, in W; the temperature to which the electrostatic clamp was heated, in degrees Celsius (° C.); and the pressure at which the heat transfer gas (helium) was supplied to the substrate, in Torr.

TABLE 1

| | FIG. 4(a) | FIG. 4(b) |
|---|---|---|
| Cl₂ flow rate (sccm) | 9 | 9 |
| Ar flow rate (sccm) | 24 | 24 |
| Pressure (mTorr) | 2 | 2 |
| Plasma source power | 1000 | 1000 |
| (W) | | |
| RF bias voltage (V) | 175 | 175 |
| RF bias power (W) | 150 | 150 |
| Electrostatic clamp | 210 | 210 |
| temperature (° C.) | | |
| Heat transfer gas | 10 | 10 |
| pressure (Torr) | | |

Measurements of parameters relating to the performance of the processes used to etch the substrates shown in FIGS. 4(a) and 4(b) and physical characteristics of the resulting etched features were taken. These are listed in Table 2 below. The measurements listed are, in the order in which they appear in the table: the average vertical etch rate achieved during the etching, in nanometres per minute (nm/min); the selectivity of the etching of the InP relative to the SiO₂ mask, given as the ratio of the InP etch rate to that of the SiO₂; the average angle of the sidewalls of the mesas relative to the notional base of the etched region, in degrees (°); the average depth of microtrenches at the base of the walls of the etched mesas, in nanometres (nm); the average depth of the microtrenches relative to the height of the mesas, as a percentage; the average height of footing at the base of the etched features relative to the heights of the etched features, as a percentage; and the uniformity of the etch rate across the surfaces etched, represented by the variation in etch rate (computed by the expression (R_{MAX}−R_{MIN})/2σ, where R_{MAX} is the maximum etch rate measured, R_{MIN} is the minimum etch rate measured, and o is the average etch rate) across the substrate as a percentage of the average etch rate.

It can be seen that the mesas 421, 422 formed in the FIG. 4(b) example have at their bases deep microtrenches 421a, 422a extending below the notional base 435 of the etched material. The relative depth of microtrenches around the mesas in the FIG. 4(a) wafer was over 20 times less, demonstrating that the provision of solid silicon exposed to the plasma achieves an excellent reduction in microtrenching, with the microtrenches that were formed being of a relative depth that is virtually negligible. The results presented in Table 2 demonstrate that the presence of solid silicon exposed to the plasma also improved the selectivity of the etching of InP relative to the SiO₂ mask and the verticality of the side walls of the mesas, which were almost exactly vertical.

TABLE 2

| | FIG. 4(a) | FIG. 4(b) |
|---|---|---|
| Etch rate (nm/min) | 739 | 1325 |
| InP:SiO₂ etch selectivity | 10.9:1 | 18.5:1 |
| Sidewall angle (°) | 89.3 | 87 |
| Microtrench depth (nm) | 8 | 336 |
| Relative microtrench | 0.23 | 5.07 |
| depth (%) | | |
| Footing (%) | 9.7 | 6.19 |
| Uniformity (%) | ±2.1 | ±3.86 |

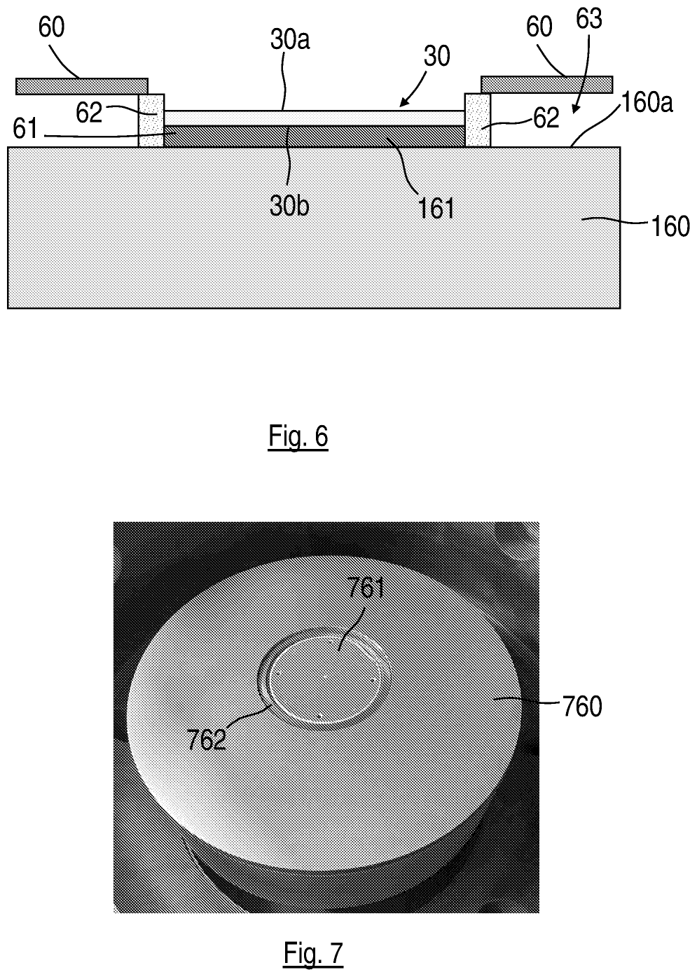

FIG. 6 shows a further example of how the substrate, substrate support structure and solid silicon may be arranged in embodiments of the invention. A substrate support structure 160 here comprises an electrostatic clamp 161, on which the substrate 30 (which comprises an indium based semiconductor material) is placed. An electrically insulating element in the form of a ring of quartz 62 is disposed on the surface of the substrate support structure 160a adjacent to (and concentric with) the substrate 30. The solid silicon 60 has a planar, annular form like in the examples shown in FIGS. 5(a) and 5(b), with a central aperture that is arranged concentric with the substrate 30 and supported on the quartz ring 62. In this arrangement, the solid silicon 60 is spaced from the substrate support structure 160 by a gap 63 (which, when the chamber is evacuated in use, will be a vacuum gap). The solid silicon 60 is electrically isolated from the substrate support structure 160 and the substrate 30 in this arrangement, so the power of the RF bias signal applied to the substrate 30 will be concentrated entirely in the area of the substrate 30. This promotes a high rate of etching.

In the FIG. 6 arrangement, preferably the electrically insulating element 62 and the solid silicon disc 60 are arranged such that the upper surface of the solid silicon exposed to the plasma is at a height of 0-5 mm, preferably 0-3 mm, more preferably 1.5-2 mm, above the surface 30a of the substrate 30 on which the patterned mask is carried, along the direction perpendicular to said surface of the substrate.

FIG. 7 is a photograph of a substrate support structure 760 which includes an electrostatic clamp 761 on which a substrate may be placed in use. The electrostatic clamp 762 is surrounded by a groove 762, which may receive a quartz ring or other annual electrically insulating element such as that described with reference to FIG. 6. The electrically insulating element may support a solid silicon disc above the substrate support structure 760 and a substrate comprising an indium based semiconductor material may be placed on the electrostatic clamp 761 in use.

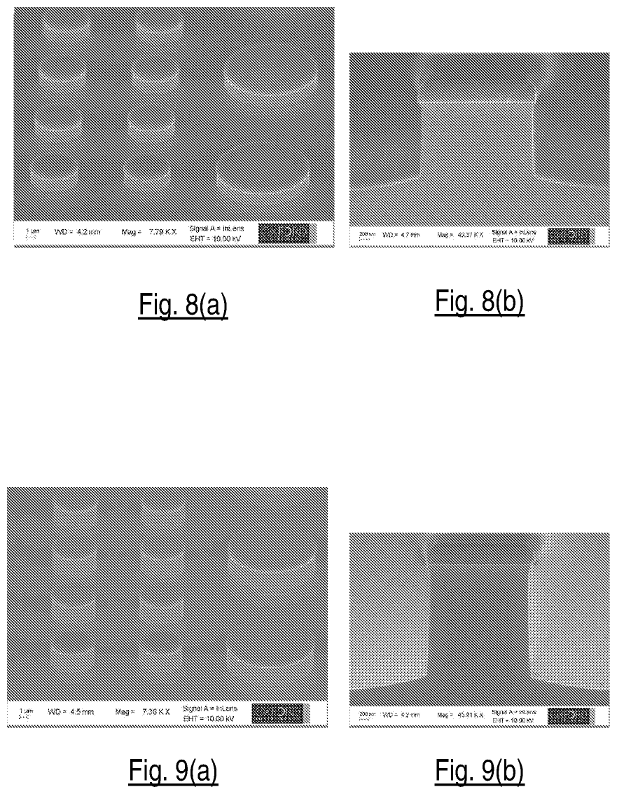

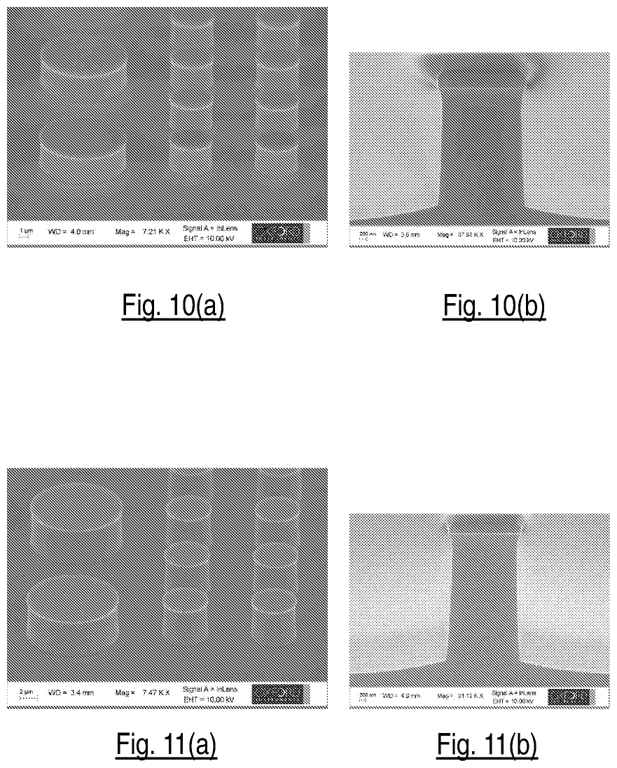

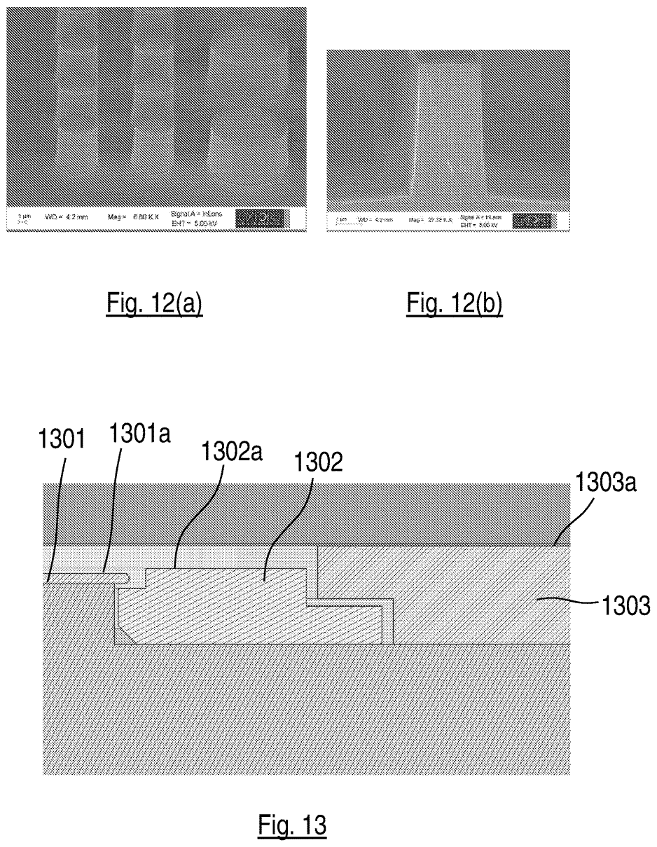

FIGS. 8(a)-12(b) are electron micrographs showing the results of experiments carried out using methods in accordance with embodiments of the invention using the arrangement of the solid silicon shown in FIG. 6. These experiments will now be described. In each pair of images (e.g. FIGS. 8(a) and 8(b), the ‘(a)’ Figure (e.g. FIG. 8(a)) shows a plurality of cylindrical features etched and the ‘(b)’ Figure (e.g. FIG. 8(b)) shows a close-up, cross-sectional view of one etched feature. While the parameters listed in Table 3 are the same for FIGS. 9(a) and 9(b) as for FIGS. 10(a) and 10(b), the substrate in the FIGS. 9(a) and 9(b) example had a greater exposed surface area (about 90%) than that in the FIGS. 10(a) and 10(b) example, where the exposed surface area was about 50%.

The parameters of the etching carried out to produce the results shown in FIGS. 8(a) to 12(b) are listed in Table 3.

TABLE 3

| | FIGS. | FIG. | FIGS. | FIGS. | FIGS. |
|---|---|---|---|---|---|
| | 8(a), (b) | 9(a), (b) | 10(a), (b) | 11(a), (b) | 12(a), (b) |
| Cl₂ flow rate | 6 | 12 | 12 | 12 | 12 |
| (sccm) | | | | | |
| Ar flow rate | 24 | 24 | 24 | 12 | 12 |
| (sccm) | | | | | |
| Pressure | 2 | 2 | 2 | 2 | 2 |
| (mTorr) | | | | | |
| Plasma source | 1000 | 1000 | 1000 | 1000 | 1000 |
| power (W) | | | | | |
| RF bias power | 150 | 150 | 150 | 150 | 150 |
| (W) | | | | | |
| Electrostatic | 210 | 210 | 210 | 210 | 190 |
| clamp | | | | | |
| temperature | | | | | |
| (° C.) | | | | | |
| Heat transfer | 10 | 10 | 10 | 10 | 10 |
| gas pressure | | | | | |
| (Torr) | | | | | |

The results of the experiments of FIGS. 8(a) to 12(b) are shown in Table 4.

TABLE 4

| | FIGS. | FIG. | FIGS. | FIGS. | FIGS. |
|---|---|---|---|---|---|
| | 8(a), (b) | 9(a), (b) | 10(a), (b) | 11(a), (b) | 12(a), (b) |
| Etch rate | 371 | 575 | 727 | 926 | 1121 |
| (nm/min) | | | | | |
| InP:SiO₂ etch | 6.2 | 7.7 | 9.8 | 11.0 | 12.5 |
| selectivity | | | | | |
| Sidewall angle | 91.1 | 90.4 | 90.4 | 89.5 | 86.6 |
| (°) | | | | | |
| Undercut per | 70 | 95 | 120 | 120 | 0 |
| side (nm) | | | | | |
| Microtrench | 0 | 0 | 0 | 0 | 95 |
| depth (nm) | | | | | |
| Relative | 0 | 0 | 0 | 0 | 1.7 |
| microtrench | | | | | |
| depth (%) | | | | | |
| Footing (%) | 16.9 | 12.8 | 12.8 | 9.2 | 5.2 |

It can be seen from the results in Table 4 that the arrangement shown in FIG. 6 achieved good etch rates with virtually no microtrenching.

FIG. 13 shows a detailed view of the arrangement of the substrate 1301, 5 electrically insulating element 1302 and solid silicon disc 1303 may be arranged in an implementation of the arrangement shown in FIG. 6. The electrically insulating element has an upper surface 1302a which is 0.675 mm above the upper surface 1301a of the substrate 1300 along the direction perpendicular to the plane of the substrate. The upper surface 1303a of the solid silicon disc 1303 is at a height of 1.825 mm relative to the upper surface 1301a of the substrate 1300.

1. A method of etching into an indium-based semiconductor material, the method comprising:
mounting a substrate comprising the indium-based semiconductor material directly on a substrate support structure in a plasma processing chamber, wherein the indium-based semiconductor material forms a surface of the substrate, said surface carrying a patterned mask and being arranged distal to the substrate support structure,
wherein the plasma processing chamber contains solid silicon arranged to be exposed to plasma generated inside the plasma processing chamber, the exposed surface area of the solid silicon being at least 1 times the area of the surface of the substrate carrying the patterned mask which is not covered by the patterned mask; the method further comprising:
establishing a flow of an etch gas mixture into the plasma processing chamber, the etch gas mixture comprising an inert gas and a chlorine-bearing gas configured to release chlorine radicals when present in plasma generated from the etch gas mixture; and
generating a plasma from the etch gas mixture within the plasma processing chamber such that the solid silicon is exposed to the plasma, thereby generating silicon-containing species in the plasma from the solid silicon, and simultaneously applying a radio frequency (RF) bias voltage to the substrate support structure, whereby the portion of the surface carrying the patterned mask that is not covered by the patterned mask is etched by the plasma comprising the generated silicon-containing species so as to form one or more etched features in the indium-based semiconductor material.

2. The method of claim 1, wherein the exposed surface area of the solid silicon is at least 3 times, preferably at least 6.5 times, more preferably at least 13 times, that of the area of the surface of the substrate carrying the patterned mask which is not covered by the patterned mask.

3. The method claim 1, wherein the solid silicon is disposed on, or laterally adjacent to, the substrate support structure.

4. The method claim 1, wherein the solid silicon laterally surrounds at least a portion, preferably all, of the perimeter of the surface of the substrate carrying the patterned mask.

5. The method claim 1, wherein the solid silicon is shaped to define an opening through the solid silicon, wherein the substrate mounted on the substrate support structure is laterally inside the opening; wherein preferably the solid silicon forms an annulus, preferably an annular disc, which defines the opening.

6. (canceled)

7. The method claim 1, wherein the solid silicon is electrically isolated from the substrate support structure and, when the substrate is mounted on the substrate support structure, from the substrate.

8. The method of claim 7, wherein the electrical isolation is provided by an electrically insulating element arranged between the solid silicon and the substrate support structure so as to space the solid silicon from the substrate support structure and the substrate when mounted on the substrate support structure; and wherein preferably:
the electrically insulating element is disposed on the substrate support structure such that it lies laterally adjacent to the substrate when the substrate is mounted on the substrate support structure, and wherein the solid silicon is supported by the electrically insulating element; and/or
the solid silicon has a central aperture arranged so as to be concentric with the substrate when the substrate is mounted on the substrate support structure; and wherein the electrically insulating element is arranged to prevent the plasma passing into the space between the solid silicon and the substrate support structure via the central aperture; and/or
the electrically insulating element has an annular form and is arranged so as to be concentric with the substrate when the substrate is mounted on the substrate support structure.

9-12. (canceled)

13. The method claim 1, wherein each part of the perimeter of the surface on which the mask is carried is laterally spaced from the exposed surface of the solid silicon by no more than 5 mm, preferably no more than 1 mm.

14. The method claim 1, wherein the solid silicon forms a substantially planar surface that is exposed to the generated plasma.

15. The method claim 1, wherein the solid silicon forms a surface that is oriented substantially parallel to the surface of the substrate carrying the patterned mask and is exposed to the generated plasma.

16. The method claim 1, wherein the solid silicon forms a surface that is arranged substantially in the plane of the surface of the substrate on which the mask is carried and is exposed to the generated plasma.

17-18. (canceled)

19. The method claim 1, wherein the method further comprises controlling the temperature of the substrate support structure during the etching, preferably such that the temperature of the substrate remains in the range of 100 to 300 degrees Celsius, preferably 150 to 250 degrees, more preferably 180 to 220 degrees; wherein controlling the temperature of the substrate preferably comprises supplying a heat transfer gas, preferably helium, between the substrate and the substrate support during the etching.

20-21. (canceled)

22. The method claim 1, further comprising controlling the temperature of the solid silicon such that the temperature of the solid silicon remains above 150 degrees Celsius and/or below 250 degrees Celsius during the etching.

23. The method claim 1, wherein the substrate support structure is an electrostatic clamp.

24. The method claim 1, wherein the substrate support structure comprises a raised portion which is raised relative to a surrounding surface of the substrate support structure, wherein the substrate is disposed on the raised portion when mounted on the substrate support structure; wherein preferably the substrate overhangs the periphery of the raised portion and the solid silicon is disposed on the surrounding surface of the substrate support structure, preferably laterally overlapping the overhanging part of the substrate.

25-27. (canceled)

28. The method claim 1, wherein the indium-based semiconductor material is indium phosphide or a ternary or quaternary alloy thereof.

29. (canceled)

30. The method claim 1, wherein the inert gas is a noble gas, preferably argon (Ar) and/or the chlorine-bearing gas is molecular chlorine (Cl₂), boron trichloride (BCl₃) or silicon tetrachloride (SiCl₄).

31. (canceled)

32. The method claim 1, wherein: the chlorine-containing gas is flowed into the plasma processing chamber at a rate in the range of 2-20 sccm, preferably 4-20 sccm, more preferably 5-15 sccm, and/or
the inert gas is flowed into the plasma processing chamber at a rate in the range of 5-50 sccm, preferably 20-50 sccm, more preferably 20-30 sccm.

33. The method claim 1, wherein the ratio of the inert gas to chlorine-bearing gas in the etch gas mixture is in the range of 1:1 to 13:1, preferably 1:1 to 5:1, preferably 2:1 to 3:1.

34. The method claim 1, wherein the etch gas mixture comprises hydrogen, wherein preferably the proportion of hydrogen in the etch gas mixture by volume is no more than 25%, preferably no more than 20%.

35-39. (canceled)
